(19) United States
(12) Patent Application Publication
(10) Pub. No.: US 2018/0322940 A1
(43) Pub. Date: Nov. 8, 2018

(54) MEMORY SYSTEM AND OPERATION METHOD OF THE SAME

(71) Applicant: SK hynix Inc., Gyeonggi-do (KR)

(72) Inventors: Yong-Ju Kim, Seoul (KR); Dong-Gun Kim, Gyeonggi-do (KR); Do-Sun Hong, Gyeonggi-do (KR)

(21) Appl. No.: 15/832,205

(22) Filed: Dec. 5, 2017

(30) Foreign Application Priority Data
May 2, 2017 (KR) 10-2017-0056084

(51) Int. Cl. G11C 29/52; G11C 13/00; G06F 11/10; G06F 3/06

(52) U.S. Cl. CPC G11C 29/52; G11C 13/0004; G11C 13/0069; G11C 2211/4062; G06F 11/1068; G06F 3/0659; G11C 13/004

(57) ABSTRACT

A method for operating a memory system includes: reading a data from a memory device; detecting and correcting an error of the data; when the error of the data is equal to or greater than a threshold value, deciding an address corresponding to memory cells from which the data is read in the memory device as a rewrite-requiring address; and rewriting the data of the memory cell corresponding to the rewrite-requiring address.

### CROSS-REFERENCE TO RELATED APPLICATIONS

The present application claims priority of Korean Patent Application No. 10-2017-0056084, filed on May 2, 2017, which is incorporated herein by reference in its entirety.

### BACKGROUND

### 1. Field

Exemplary embodiments of the present disclosure relate to a memory system including a memory device and a memory controller for controlling the memory device.

### 2. Description of the Related Art

Recently, researchers and the industry are focusing to develop next-generation memory devices for replacing the Dynamic Random Access Memory (DRAM) and the flash memory. Among the next-generation memory devices is a resistive memory device using a variable resistance material, i.e., a material capable of switching between at least two different resistance states as the resistance is drastically changed according to a bias applied thereto. Non-limiting examples of a resistive memory device include a Phase-Change Random Access Memory (PCRAM) device, a Resistive Random Access Memory (RRAM) device, a Magnetic Random Access Memory (MRAM) device, and a Ferroelectric Random Access Memory (FRAM) device.

A typical resistive memory device may have a memory cell array with a cross point array structure having a plurality of bottom electrodes (e.g., a plurality of row lines (or word lines)) and a plurality of top electrodes (e.g., a plurality of column lines (or bit lines)) crossed with each other and memory cells disposed at the cross points. Each memory cell may include a variable resistance device and a selection device serially coupled.

Although the resistive memory device is developed as a non-volatile memory device, a drift phenomenon where a resistance value varies as time passes after a data is written in a memory cell may occur causing the loss of data. Therefore, it would be desirable to develop a solution to address the loss of data in restrictive memory devices.

### SUMMARY

Embodiments of the present invention are directed to a memory system including at least one memory device that may efficiently prevent data loss of memory cells of the memory device. The memory device may be a resistive memory device.

In accordance with an embodiment of the present invention, a method for operating a memory system includes: reading a data from a memory device; detecting and correcting an error of the data; when the error of the data is equal to or greater than a threshold value, deciding an address corresponding to memory cells from which the data is read in the memory device as a rewrite-requiring address; and rewriting the data of the memory cells corresponding to the rewrite-requiring address.

The reading of the data, the detecting and correcting of the error of the data, and the deciding of the address corresponding to the memory cells may be performed upon a request from a host.

The rewriting of the data of the memory cells may include: reading the data of the memory cells corresponding to the rewrite-requiring address; detecting and correcting an error of the read data so as to produce an error-corrected data; and writing the error-corrected data in the memory cell corresponding to the rewrite-requiring address.

In the rewriting of the data of the memory cells may include when it is impossible to correct the error of the read data, repeatedly changing a voltage level of a read voltage that is used in the memory device and performing the operation of reading the data of the memory cells corresponding to the rewrite-requiring address.

The reading of the data, the detecting and correcting of the error of the data, and the deciding of the address corresponding to the memory cells may be performed periodically while changing the memory cells from which the data is read, when the error of the data is equal to or greater than a threshold value.

The memory device may include a plurality of memory cells, and each of the plurality of the memory cells may include a resistive memory element and a selection element.

The resistive memory element may be a phase-change memory device.

In accordance with another embodiment of the present invention, a memory system includes: a memory device including a plurality of memory cells; and a memory controller suitable for reading a data from the memory device, and when an error of data is equal to or greater than a threshold value, deciding an address corresponding to memory cells from which the data is read as a rewrite-requiring address.

The memory controller may rewrite the data of the memory cells corresponding to the rewrite-requiring address.

The memory controller may read the data from the memory device in response to a read operation request from a host, and when an error of the data is equal to or greater than a threshold value, the memory controller may perform an operation of deciding the address corresponding to the memory cells from which the data is read as the rewrite-requiring address.

The memory controller may read the data from the memory device, and when an error of the data is equal to or greater than a threshold value, the memory controller may periodically perform the operation of deciding the address corresponding to the memory cells from which the data is read as the rewrite-requiring address while changing the memory cells from which the data is read.

During the rewrite operation, the memory controller may read the data from the memory cells of the memory device corresponding to the rewrite-requiring address, detect and correct an error of the data so as to produce an error-corrected data, and write the error-corrected data in the memory cells of the memory device corresponding to the rewrite-requiring address.

During the rewrite operation, when it is impossible to correct the error of the read data, the memory controller may periodically perform an operation of reading the data from the memory cells corresponding to the rewrite-requiring address while changing a voltage level of a read voltage that is used in the memory device until the error of the read data becomes correctable.

The memory controller may include: an error-correction circuit suitable for detecting and correcting an error of the data read from the memory device so as to produce an error-corrected data; a rewrite-requiring address storing circuit suitable for storing the rewrite-requiring address; and a rewrite circuit suitable for rewrite the data of the memory cells corresponding to the rewrite-requiring address.

The memory controller may include: a host interface suitable for communication with a host; a scheduler suitable for deciding a process order of requests of the host; a command generator suitable for generating a command to be applied to the memory device; a memory interface suitable for communication with the memory device; and a read retry circuit suitable for controlling a read retry operation of the memory device.

Each of plurality of the memory cells may include: a resistive memory element; and a selection element.

The resistive memory element may be a phase-change memory device.

### BRIEF DESCRIPTION OF THE DRAWINGS

FIG. 1 illustrates an exemplary resistive memory cell of a resistive memory device.

FIG. 2 is a graph illustrating an exemplary I-V curve of a resistive memory cell.

FIGS. 3A and 3B are graphs illustrating a threshold voltage distribution of memory cells of a resistive memory device.

FIG. 4 is a block diagram illustrating a memory system, in accordance with an embodiment of the present disclosure.

FIG. 5 is a flowchart illustrating an information collecting operation on memory cells that require a rewrite operation in a memory system, in accordance with an embodiment of the present disclosure.

FIG. 6 is a flowchart illustrating an information collecting operation on memory cells that require a rewrite operation in a memory system, in accordance with another embodiment of the present disclosure.

FIG. 7 is a flowchart illustrating a rewrite operation in a memory system in accordance with an embodiment of the present disclosure.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

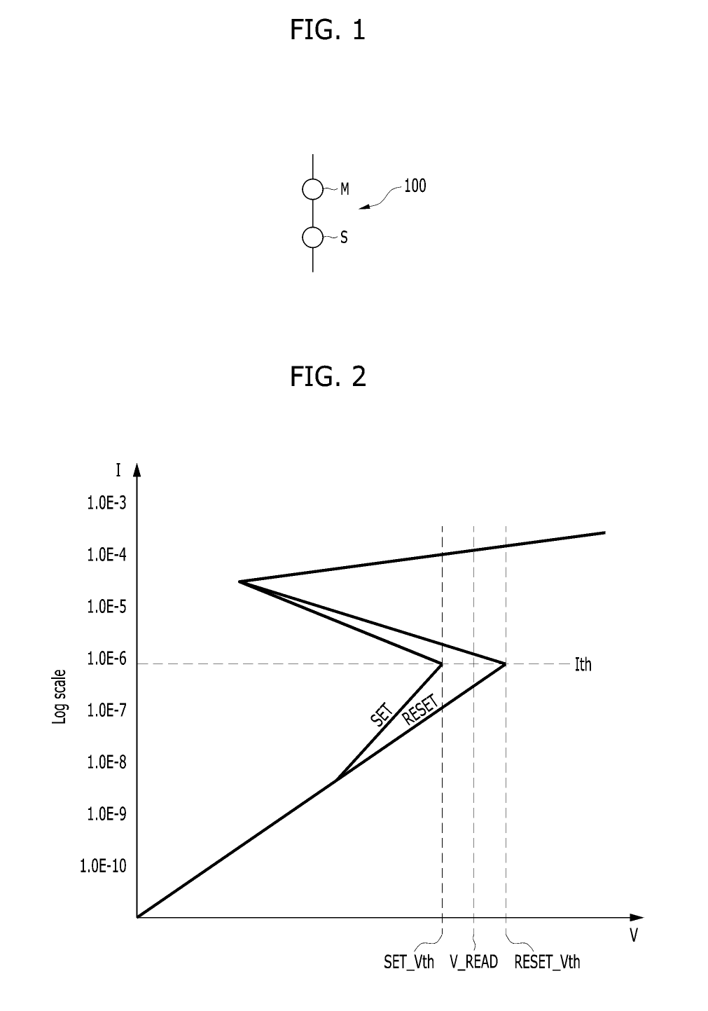

FIG. 1 illustrates a resistive memory cell 100 of a resistive memory device. FIG. 2 is a graph illustrating an I-V curve of a resistive memory cell, for example, the resistive memory cell 100 of FIG. 1.

Referring to FIG. 1, the resistive memory cell 100 may include a resistive memory element M and a selection element S.

The resistive memory element M may be in a low resistance state (which is a set state SET) or a high resistance state (which is a reset state RESET) based on the data stored therein. For example, the resistive memory element M may be a phase-change memory device, wherein when the resistive memory element M is in a crystalline state, the resistance value of the resistive memory element M may be low, and when the resistive memory element M is in an amorphous state, the resistance value the resistive memory element M may be high.

When the selection element S is turned off, a small amount of current flows, and then when the amount of current flowing through a memory cell goes over a threshold value Ith, the selection element S is turned on, thus making much more current flow than the amount of current flowing before the selection element S is turned on. The selection element S may go through a snapback phenomenon where the voltage level at both ends of the resistive memory cell 100 is drastically decreased after the selection element S is turned on. The selection element S may be an ovonic threshold switch (OTS).

FIG. 2 shows the current flowing through a resistive memory cell, for example, the resistive memory cell 100 of FIG. 1 based on the voltage applied to both ends of the resistive memory cell 100. Whether the resistive memory cell 100 is in a high resistance state RESET or the resistive memory cell 100 is in a low resistance state SET, as the voltage level of the voltage applied to both ends becomes higher, the amount of current flowing through the resistive memory cell 100 is increased. At the same voltage level, more current may flow in the resistive memory cell 100 with the low resistance state SET than in the resistive memory cell 100 with the high resistance state RESET.

When the voltage of both ends of the resistive memory cell 100 which is in the low resistance state SET reaches a threshold value SET_Vth of a low resistance state, in other words, when the amount of current flowing through the resistive memory cell 100 in the low resistance state SET reaches the threshold value Ith, the selection element S of the resistive memory cell 100 in the low resistance state SET may be turned on and the snapback phenomenon where the voltage level at both ends of the resistive memory cell 100 is drastically decreased and the amount of current flowing through the resistive memory cell 100 is drastically increased may occur.

When the voltage at both ends of the resistive memory cell 100 which is in the high resistance state RESET reaches a threshold value RESET_Vth of a high-resistance state, in other words, when the amount of current flowing through the resistive memory cell 100 in the high resistance state RESET reaches the threshold value Ith, the selection element S of the resistive memory cell 100 in the high resistance state RESET may be turned on and the snapback phenomenon where the voltage level at both ends of the resistive memory cell 100 is drastically decreased and the amount of current flowing through the resistive memory cell 100 is drastically increased may occur.

The data stored in the resistive memory cell 100 may be read by using the snapback phenomenon. When a read voltage V_READ which is greater than the threshold value SET_Vth of a low resistance state and less than the threshold value RESET_Vth of a high resistance state is applied to both ends of the resistive memory cell 100 and when the resistive memory cell 100 is in a low resistance, the snapback phenomenon occurs in the resistive memory cell 100 and a large amount of current flows through the resistive memory cell 100. When a read voltage V_READ which is greater than the threshold value SET_Vth of a low resistance state and less than the threshold value RESET_Vth of a high resistance state is applied to both ends of the resistive memory cell 100 and the resistive memory cell 100 is in a high resistance, the snapback phenomenon does not occur in the resistive memory cell 100 and thus a small amount of current may flow through the resistive memory cell 100. Therefore, it is possible to determine whether the resistive memory cell 100 is in a low resistance state or in a high resistance state by applying the aforementioned read voltage V_READ to both ends of the resistive memory cell 100 and sensing the amount of current flowing through the resistive memory cell 100.

The data of the resistive memory cell 100 may be written (or programmed) by applying a write current to the resistive memory cell 100 and sending the resistive memory element M of the resistive memory cell 100 into a melting state. When the write current is gradually decreased after the resistive memory element M of the resistive memory cell 100 is sent into a melting state, the state of the resistive memory element M becomes a crystalline state and thus the state of the resistive memory element M may become a low resistance state. When the write current is rapidly decreased after the resistive memory element M of the resistive memory cell 100 is sent into a melting state, the state of the resistive memory device M becomes an amorphous state and thus the state of the resistive memory element M may become a high resistance state.

The resistance value of the resistive memory element M of the resistive memory cell 100 may be changed due to a drift phenomenon as time passes. Also, it has been observed that the resistance value of the selection element S may be changed due to the drift phenomenon as time passes. In short, the data stored in the resistive memory cell 100 may get lost due to the drift phenomenon.

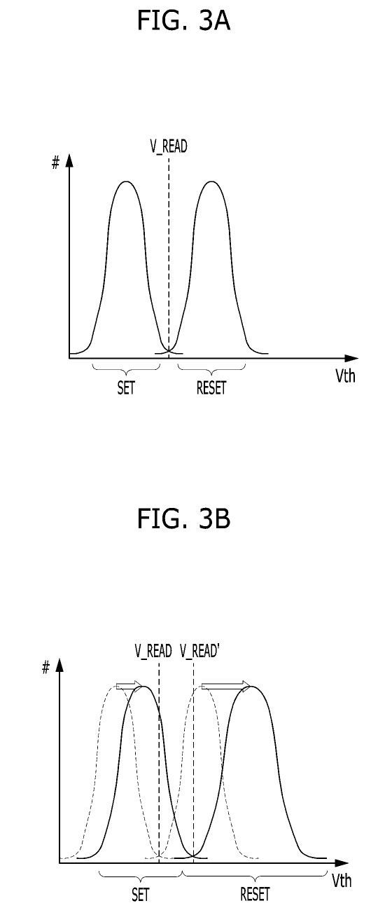

FIGS. 3A and 3B are graphs illustrating threshold voltage distribution of memory cells of a resistive memory device. FIG. 3A shows a threshold voltage Vth distribution of the memory cells after a data is written. The X axis represents threshold voltages Vth, and the Y axis represents the number of memory cells #. When the threshold voltage Vth distribution of the memory cells is as shown in FIG. 3A, memory cells in the set state SET and memory cells in the reset state RESET may be distinguished from each other based on the read voltage V_READ.

FIG. 3B shows what changes occur in the threshold voltage distribution of FIG. 3A when that a predetermined time passes due to the drift phenomenon occurring in the memory cells. It may be seen in FIG. 3B that all the threshold voltage values of the memory cells in the set state SET and the memory cells in the reset state RESET are increased and shift to the right. When the drift phenomenon occurs, the memory cells in the set state SET and the memory cells in the reset state RESET have to be distinguished from each other based on a greater read voltage V_READ′. Although a drift value has a tendency of increasing as time passes, the drift value is not uniform. Therefore, it is difficult to appropriately control the value of the read voltage V_READ′ and when drift occurs much, the data stored in the memory cells may get lost.

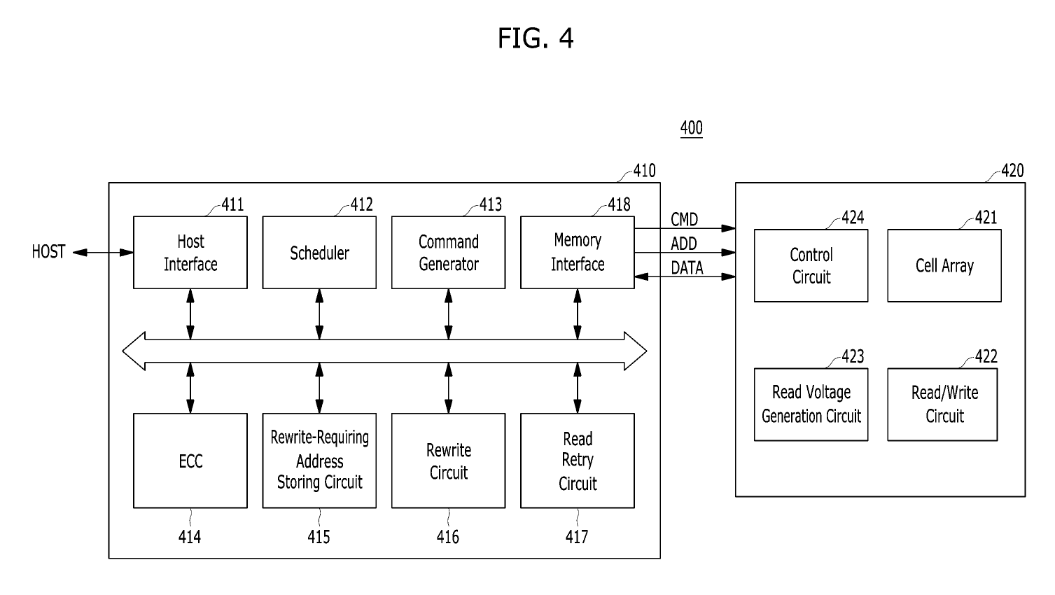

FIG. 4 is a block diagram illustrating a memory system 400 in accordance with an embodiment of the present disclosure.

Referring to FIG. 4, the memory system 400 may include a memory controller 410 and a memory device 420.

The memory controller 410 may control the operation of the memory device 420 upon receiving a request from a host. The host may be a central processing unit (CPU), a graphic processing unit (GPU), or an application processor (AP). The memory controller 410 may include a host interface 411, a scheduler 412, a command generator 413, an error correction circuit 414, a rewrite-requiring address storing circuit 415, a rewrite circuit 416, a read retry circuit 417, and a memory interface 418.

The host interface 411 may be an interface between the memory controller 410 and the host. Requests of the host may be received through the host interface 411, and process results of the requests may be transferred to the host through the host interface 411.

The scheduler 412 may decide an order for the requests to be directed to the memory device 420 among the requests received from the host. The scheduler 412 may decide the order for the requests to be directed to the memory device 420 differently from the order that the requests are received from the host to increase the performance of the memory device 420. For example, although the host requests for a read operation of the memory device 420 first and then requests for a write operation of the memory device 420, the scheduler 412 may control the order of the requests to perform the write operation prior to the read operation.

The command generator 413 may generate commands to be applied to the memory device 420 according to the order of the operations that is decided by the scheduler 412.

The error correction circuit 414 may generate an error correction code (ECC) based on a write data during a write operation. The error correction code generated in the error correction circuit 414 may be stored in the memory device 420 along with the write data. The error correction circuit 414 may detect and correct an error of a read data during a read operation based on the error correction code. The number of detectable error bits by the error correction circuit 414 may be greater than the number of error correctable bits. For example, the error correction circuit 414 may be able to correct errors of M bits (where M is an integer equal to or greater than 1) among the read data that are read at once (e.g., read data of one page), and detect errors of M+1 bits. In short, the error correction circuit 414 may be able to correct an error of M bits and correct an error of M+1 bits.

The rewrite-requiring address storing circuit 415 may store an address corresponding to memory cells that require a rewrite operation in the memory device 420 as a rewrite-requiring address. During a read operation, an address corresponding to memory cells from which an error of a threshold value or greater is detected by the error correction circuit 414 may be stored in the rewrite-requiring address storing circuit 415 as a rewrite-requiring address.

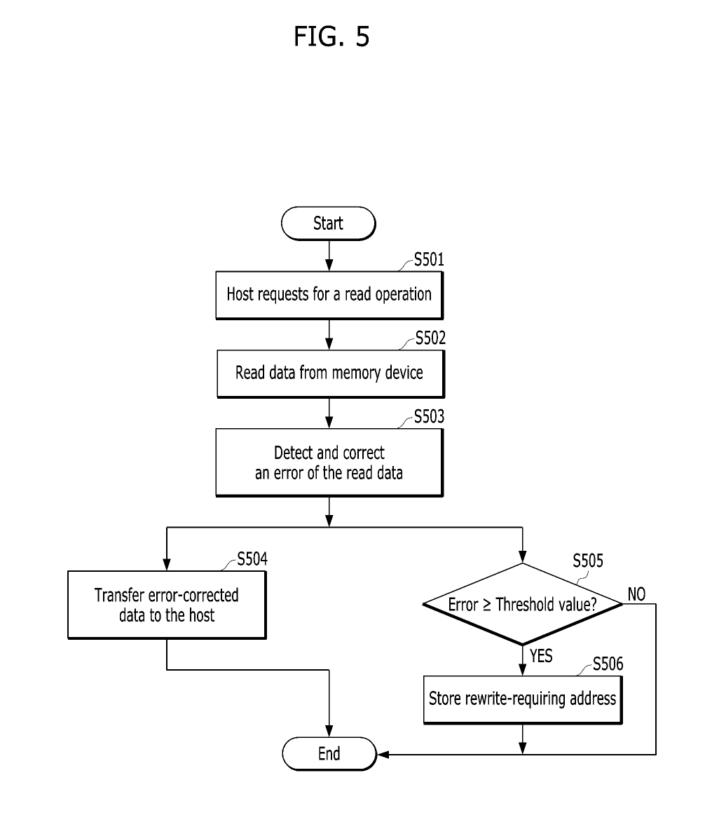

The rewrite circuit 416 may perform a rewrite operation onto memory cells corresponding to the rewrite-requiring address that is stored in the rewrite-requiring address storing circuit 415. The memory cells onto which the rewrite operation is performed may be protected from losing data. The rewrite operation and the rewrite circuit 416 will be described later in detail with reference to FIGS. 5 to 7.

The read retry circuit 417 may be a circuit for controlling a read retry operation which is performed when an error of a data read from the memory device 420 is not corrected by the error correction circuit 414. The read retry operation is an operation of repeating a read operation again and may include changing the voltage level of a read voltage which is used for the read operation of the memory device 420.

The memory interface 418 provides an interface between the memory controller 410 and the memory device 420. A command CMD and an address ADD may be transferred from the memory controller 410 to the memory device 420 through the memory interface 418, and data may be transferred and received between the memory controller 410 and the memory device 420 through the memory interface 418. The memory interface 418 may also be called a physical PHY interface.

The memory device 420 may perform a read operation and/or a write operation under the control of the memory controller 410. The voltage level of the read voltage VREAD that is used in the memory device 420 may be set by the memory controller 410. The memory device 420 may include a cell array 421, a read/write circuit 422, a read voltage generation circuit 423, and a control circuit 424. The memory device 420 may be a resistive memory device which is described above with reference to FIGS. 1 to 3, but the concept and spirit of the present invention are not limited to it and the memory device 420 may be a memory device of another kind.

The cell array 421 may include a plurality of memory cells. The read/write circuit 422 may write data in memory cells that are selected based on an address ADD among the memory cells of the cell array 421, or read data from the selected memory cells among the memory cells of the cell array 421 based on the address ADD. The read/write circuit 422 may receive a data to be written from the memory controller 410 during a write operation, and transfer a read data to the memory controller 410 during a read operation. The read voltage generation circuit 423 may generate the read voltage VREAD to be used for a read operation. The voltage level of the read voltage VREAD generated by the read voltage generation circuit 423 may be set by the memory controller 410. The control circuit 424 may control the cell array 421, the read/write circuit 422, and the read voltage generation circuit 423 to perform a read operation, a write operation, and/or a setup operation that are/is directed by a command CMD which is received from the memory controller 410.

FIG. 5 is a flowchart illustrating an information collecting operation on memory cells that require a rewrite operation in a memory system, for example, the memory system 400 of FIG. 4 in accordance with an embodiment of the present disclosure.

Referring to FIG. 5, first of all, a read request for a read operation may be transferred from the host to the memory controller 410 in step S501. The read request may include address information designating or indicating memory cells onto which the read operation is to be performed in the memory device 420. The address information may be a logical address which can be translated into a physical address of the memory device 420 by the controller 410 according to well-known schemes.

In step S502, the memory controller 410 may apply a command CMD for a read operation and an address ADD designating memory cells onto which the read operation is to be performed to the memory device 420 in response to a read request in the step S501, and a data read from the memory device 420 may be transferred to the memory controller 410. The data may include a normal data and an error correction code (ECC).

In step S503, the error correction circuit 414 of the memory controller 410 may detect and correct an error of the data that is read in the step S502. In step S504, the memory controller 410 may transfer the data whose error is corrected in the step S503 to the host.

In step S505, the memory controller 410 may compare the error detected in the step S503 with a threshold value. When the error detected in the step S503 is equal to or greater than the threshold value (YES in the step S505), it may be decided that the data is highly likely to be lost, and the address corresponding to the memory cells from which the data is read in the step S502 may be decided as a rewrite-requiring address and stored in the rewrite-requiring address storing circuit 415 in step S506. Herein, the threshold value may be set to be less than M, which is the number of bits that may be error-corrected by the error correction circuit 414. For example, when the number of bits that may be error-corrected by the error correction circuit 414 is 8 bits, the threshold value may be set to 6 bits. This means that a 6-bit error has occurred and the error correction circuit 414 may be able to correct an error of up to 8 bits. This signifies that the error may occur as many as they are not error-corrected by the error correction circuit 414 in the future. In other words, the possibility that the data is lost is high.

The operation of collecting rewrite-requiring addresses, which is described above with reference to FIG. 5, may be performed whenever a read operation is performed upon the request of the host. Therefore, the rewrite-requiring address collecting operation of FIG. 5 may be advantageous in that the additional operation for collecting the rewrite-requiring addresses may be minimized while not deteriorating the performance of the memory system 400. However, since only the memory cells where a read operation is performed are subject to the rewrite-requiring address collecting operation, memory cells where a read operation has not been performed for a long time may be excluded.

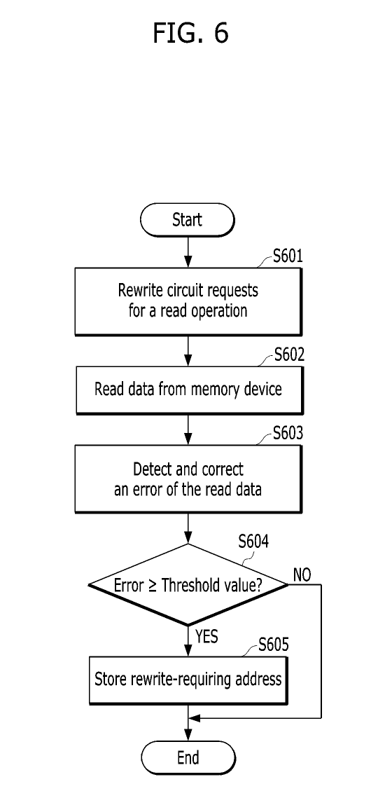

FIG. 6 is a flowchart illustrating an information collecting operation on memory cells that require a rewrite operation in a memory system, for example, the memory system 400 of FIG. 4 in accordance with another embodiment of the present disclosure.

Referring to FIG. 6, first of all, a read operation may be requested by the rewrite circuit 416 in step S601. In FIG. 5, the read operation is started according to a request of the host. However, in FIG. 6, the read operation is started according to a request of the rewrite circuit 416. The read operation request of the rewrite circuit 416 in the step S601 may be periodically performed, and an address designating or indicating memory cells onto which a read operation is to be performed may be changed whenever a read operation is requested. In some embodiments, the period of the read operation request of the rewrite circuit 416 may be decided as every time when a predetermined time passes, or every time when a write operation is performed in a predetermined number of times.

In step S602, the memory controller 410 may apply a command CMD for a read operation and an address ADD designating memory cells onto which the read operation is to be performed to the memory device 420 in response to a read operation request in the step S601, and a data read from the memory device 420 may be transferred to the memory controller 410. The data may include a normal data and an error correction code (ECC).

In step S603, the error correction circuit 414 of the memory controller 410 may detect and correct an error of the data that is read in the step S602. The read operation of FIG. 6 is performed to collect information on memory cells requiring a rewrite operation, and the read operation of FIG. 6 is not performed upon a request of the host. Therefore, in FIG. 6, no read data is transferred to the host as it is in FIG. 5.

In step S604, the memory controller 410 may compare the error detected in the step S603 with a threshold value. When the error detected in the step S603 is equal to or greater than the threshold value (YES in the step S604), it may be decided that the data is highly likely to be lost, and the address corresponding to the memory cells from which the data is read in the step S602 may be decided as a rewrite-requiring address and stored in the rewrite-requiring address storing circuit 415 in step S605.

The operation of collecting rewrite-requiring addresses, which is described above with reference to FIG. 6, may be performed periodically upon the request of the rewrite circuit 416. Therefore, it may need to perform an additional operation (it may take additional time) to collect the rewrite-requiring addresses. However, since the rewrite-requiring address collecting operation is performed periodically while changing the address, the rewrite-requiring address collecting operation may be subject to all the memory cells of the memory device 420.

To collect the rewrite-requiring addresses in the memory system 400, the method of FIG. 5 or the method of FIG. 6 may be used. Also, both of the method of FIG. 5 and the method of FIG. 6 may be used.

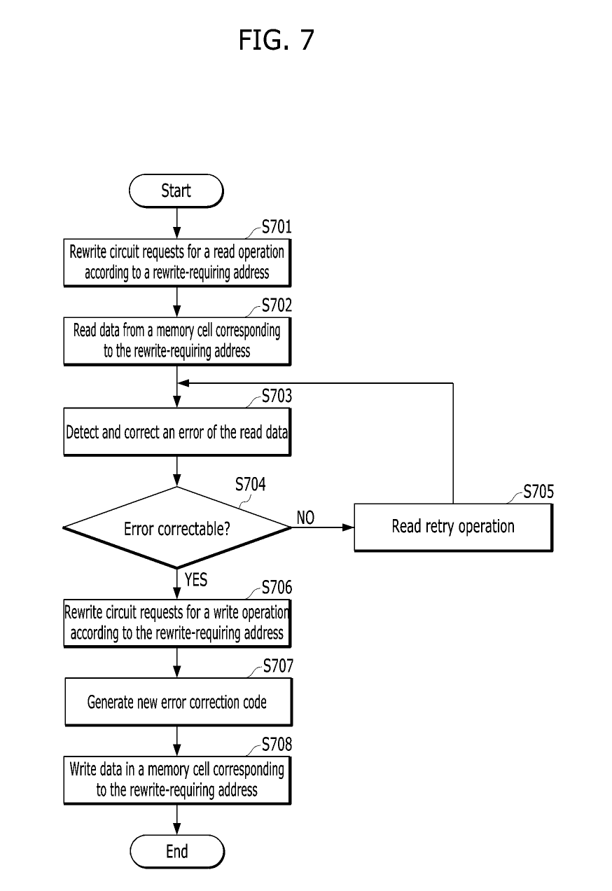

FIG. 7 is a flowchart illustrating a rewrite operation in a memory system, for example, the memory system 400 of FIG. 4, in accordance with an embodiment of the present disclosure.

Referring to FIG. 7, first of all, the rewrite circuit 416 may request for a read operation for a memory cells corresponding to a rewrite-requiring address which is stored in the rewrite-requiring address storing circuit 415 in step S701. A read operation request of the rewrite circuit 416 in the step S701 may be performed at a predetermined period. In some embodiments, the period may be decided as every time when a predetermined time passes, or every time when a write operation is performed in a predetermined number of times. When there is no rewrite-requiring address stored in the rewrite-requiring address storing circuit 415, the operation of the step S701 may not be performed.

In response to the request in the step S701, the memory controller 410 may apply a command CMD and an address ADD for a read operation to the memory device 420 in response to a read operation request in the step S701, and a data read from the memory device 420 may be transferred to the memory controller 410 in step S702. In some embodiments, the address ADD applied from the memory controller 410 to the memory device 420 may be a rewrite-requiring address. The data may include a normal data and an error correction code (ECC).

In step S703, the error correction circuit 414 of the memory controller 410 may detect and correct an error of the data that is read in the step S702.

In step S704, the memory controller 410 may decide whether the error in the step S703 is correctable. When it is impossible to correct the error in the step S703 (NO in step S704), for example, when the error of the read data includes M+1 bits, which is greater than the error-correctable bits M, a read retry operation may be performed in step S705. The read retry operation may be performed under the control of the read retry circuit 417. The read retry circuit 417 may change the voltage level of the read voltage VREAD that is generated in the read voltage generation circuit 423 of the memory device 420 and then control the memory device 420 to perform a read operation again. The operations of the steps S705, S703 and S704 are repeated until the error is correctable.

When it is possible to correct the error in the step S703, (i.e., YES in step S704), for example, when the number of the error bits of the read data is equal to or less than the error-correctable bits M, the rewrite circuit 416 may request the memory device 420 to perform a write operation of writing the error-corrected data obtained in the step S703 onto a memory cells corresponding to the rewrite-requiring address in step S706.

In response to the request in the step S706, the error correction circuit 414 may generate a new error correction code (ECC) in the step S707, based on the error-corrected data obtained in the step S703.

The memory controller 410 may then apply to the memory device 420 the command CMD for a write operation, the address ADD which is the same as the address in the step S702, the error-corrected data obtained in the step S703, and the error correction code (ECC) generated in the step S706. In this way, data may be re-written in the memory cells which correspond to the rewrite-requiring address of the memory device 420 in step S708.

After the step S708, the rewrite-requiring address that is used for the rewrite operation in the step S708 may be erased from the rewrite-requiring address storing circuit 415.

Through the method described in FIG. 7, the rewrite operation for the memory cells corresponding to the rewrite-requiring address that is collected by the method of FIG. 5 and/or the method of FIG. 6 may be performed, and loss of data may be prevented.

According to the embodiments of the present disclosure, it is possible to efficiently prevent data of memory cells from being lost.

While the present invention has been described with respect to specific embodiments, it will be apparent to those skilled in the art that various changes and modifications may be made without departing from the spirit and scope of the invention as defined in the following claims.

What is claimed is:

1. A method for operating a memory system, comprising:
reading a data from a memory device;
detecting and correcting an error of the data;
when the error of the data is equal to or greater than a threshold value, deciding an address corresponding to memory cells from which the data is read in the memory device as a rewrite-requiring address; and
rewriting the data of the memory cells corresponding to the rewrite-requiring address.

2. The method of claim 1, wherein the reading of the data, the detecting and correcting of the error of the data, and the deciding of the address corresponding to the memory cells are performed upon a request from a host.

3. The method of claim 1, wherein the rewriting of the data of the memory cells includes:
reading the data of the memory cells corresponding to the rewrite-requiring address;
detecting and correcting an error of the read data so as to produce an error-corrected data; and
writing the error-corrected data in the memory cells corresponding to the rewrite-requiring address.

4. The method of claim 3, wherein the rewriting of the data of the memory cells includes
when it is impossible to correct the error of the read data, repeatedly changing a voltage level of a read voltage that is used in the memory device and performing the operation of reading the data of the memory cells corresponding to the rewrite-requiring address.

5. The method of claim 1, wherein the reading of the data, the detecting and correcting of the error of the data, and the deciding of the address corresponding to the memory cells are performed periodically while changing the memory cells from which the data is read, when the error of the data is equal to or greater than a threshold value.

6. The method of claim 1, wherein the memory device includes a plurality of memory cells, and
each of the plurality of the memory cells includes a resistive memory element and a selection element.

7. The method of claim 6, wherein the resistive memory element includes a phase-change memory device.

8. A memory system, comprising:
a memory device including a plurality of memory cells; and
a memory controller suitable for reading a data from the memory device, and when an error of the data is equal to or greater than a threshold value, deciding an address corresponding to memory cells from which the data is read as a rewrite-requiring address.

9. The memory system of claim 8, wherein the memory controller rewrites the data of the memory cells corresponding to the rewrite-requiring address.

10. The memory system of claim 8, wherein the memory controller reads the data from the memory device in response to a read operation request from a host, and
when an error of the data is equal to or greater than a threshold value, the memory controller performs an operation of deciding the address corresponding to the memory cells from which the data is read as the rewrite-requiring address.

11. The memory system of claim 8, wherein the memory controller reads the data from the memory device, and
when an error of the data is equal to or greater than a threshold value, the memory controller periodically performs the operation of deciding the address corresponding to the memory cells from which the data is read as the rewrite-requiring address while changing the memory cells from which the data is read.

12. The memory system of claim 9, wherein during the rewrite operation, the memory controller reads the data from the memory cells of the memory device corresponding to the rewrite-requiring address, detects and corrects an error of the data so as to produce an error-corrected data, and writes the error-corrected data in the memory cells of the memory device corresponding to the rewrite-requiring address.

13. The memory system of claim 12, wherein during the rewrite operation, when it is impossible to correct the error of the read data, the memory controller periodically performs an operation of reading the data from the memory cells corresponding to the rewrite-requiring address while changing a voltage level of a read voltage that is used in the memory device until the error of the read data becomes correctable.

14. The memory system of claim 9, wherein the memory controller includes:
an error-correction circuit suitable for detecting and correcting an error of the data read from the memory device so as to produce an error-corrected data;
a rewrite-requiring address storing circuit suitable for storing the rewrite-requiring address; and
a rewrite circuit suitable for rewrite the data of the memory cell corresponding to the rewrite-requiring address.

15. The memory system of claim 14, wherein the memory controller includes:
a host interface suitable for communication with a host;
a scheduler suitable for deciding a process order of requests of the host;
a command generator suitable for generating a command to be applied to the memory device;
a memory interface suitable for communication with the memory device; and
a read retry circuit suitable for controlling a read retry operation of the memory device.

16. The memory system of claim 8, wherein each of plurality of the memory cells includes:
a resistive memory element; and
a selection element.

17. The memory system of claim 16, wherein the resistive memory element is a phase-change memory device.
